(19) United States
(12) Patent Application Publication
(10) Pub. No.: US 2017/0349496 A1
(43) Pub. Date: Dec. 7, 2017

(54) PRODUCTION METHOD OF NUCLEAR REACTOR STRUCTURE

(71) Applicant: IBIDEN CO., LTD., OGAKI-SHI, GIFU (JP)

(72) Inventors: Takashi TAKAGI, IBI-GUN, GIFU (JP); Masahiro YASUDA, OGAKI-SHI, GIFU (JP)

(73) Assignee: BIDEN CO., LTD, Ogaki-shi, Gifi (JP)

(21) Appl. No.: 15/538,375

(22) PCT Filed: Dec. 17, 2015
(86) PCT No.: PCT/JP2015/085400

§ 371 Date: Jun. 21, 2017

(30) Foreign Application Priority Data
Dec. 22, 2014 (JP) 2014-258777

(51) Int. Cl. C04B 35/80; G21C 5/12; C23C 16/44; G21C 11/06; C23C 16/42

(52) U.S. Cl. CPC C04B 35/80; G21C 11/06; C23C 16/42; C23C 16/44; G21C 5/12

(57) ABSTRACT

A nuclear reactor structure configuring a pebble accommodating space of a pebble bed type nuclear reactor includes a core material including graphite and a ceramic/ceramic composition material covering a surface of the core material. According to a core material processing step (A) of processing the core material including graphite into a quadrangular prism, a bottom surface of which is an approximately isosceles trapezoid, a step (B) of obtaining a base material by covering the core material with an aggregate including a ceramic fiber, and a CVD step (C) of putting the base material into a CVD reactor and forming a SiC matrix in gaps of the aggregate, thereby forming a ceramic/ceramic composite material on a surface of the core material, the nuclear reactor structure capable of enhancing durability, preventing cracking, etc. from occurring, and preventing exposure of graphite as the core material from occurring, can be provided.

### TECHNICAL FIELD

The present invention relates to a production method of a nuclear reactor structure for nuclear reactors.

### BACKGROUND ART

In view of the facts that since graphite that is utilized as a core material of a nuclear reactor structure has a high neutron absorption cross section and large capability for neutron moderation, it has a high neutron moderation ratio and high heat resistance and is easy to provide large materials, the graphite is utilized as a neutron moderator or a reflector of nuclear reactors. In particular, the graphite is an important material as materials of neutron moderators, reflectors, and so on for gas-cooled reactors, such as a magnox reactor, an advanced graphite reactor (AGR reactor), a high temperature gas-cooled reactor, etc.

Patent Document 1 discloses a graphite structure having enhanced strength without impairing nuclear and thermal performances, by covering a surface of a nuclear reactor structure configured by solid graphite, such as a neutron moderator, a reflector, etc., by a heat-resistant ceramic, such as silicon carbide SiC, etc., or the like.

### CITATION LIST

### Patent Document

Patent Document 1: JP-U-S61-206897

### SUMMARY OF INVENTION

### Technical Problem

In order to stably operate a nuclear reactor, various movable mechanisms, such as a control rod, etc., are provided in the inside thereof. In addition, for the purpose of exchange or maintenance of a nuclear fuel, or the like, there is a case where members, nuclear fuels, and the like of the inside of the nuclear reactor are carried in or carried out. Then, as for the nuclear reactor, for example, in a high temperature gas-cooled reactor using helium as a coolant, there are exemplified a block type high temperature gas-cooled reactor and a pebble bed type high temperature gas-cooled reactor according to a difference of the fuel shape.

The block type high temperature gas-cooled reactor is, for example, configured by a hexagonal graphite block (fuel column) having fuel rods accommodated in the inside thereof, a hexagonal graphite block (movable reflector) not having fuel rods accommodated in the inside thereof, and a permanent reflector surrounding the outsides of the foregoing graphite blocks. In addition, the graphite structure of Patent Document 1 is a technology concerning the block type high temperature gas-cooled reactor.

On the other hand, in the pebble bed type high temperature gas-cooled reactor, a fuel ball (pebble) formed by mixing covered fuel particles and graphite particles and molding the mixture in a spherical shape is used, and a plurality of such fuel balls are piled up at random within a space formed of a graphite block to form a reactor core. A diameter of the fuel ball is about 6 cm. The pebble bed type high temperature gas-cooled reactor is characterized in that the fuel balls, a nuclear reaction of which has been reduced, are taken out from the lower part during the operation, and at the same time, new fuel balls are supplied from the upper part, thereby continuously exchanging the fuel balls. For this reason, according to the pebble bed type high temperature gas-cooled reactor, the matter that the operation is stopped to exchange the fuel as in the block type high temperature gas-cooled reactor is not needed, so that an operation period of the nuclear reactor can be made long.

However, in the block type high temperature gas-cooled reactor, there is a case where friction occurs in the heat-resistance ceramic following the motion of the control rod or movable reflector, and furthermore, on the occasion of exchanging the graphite block, an impact is applied to the heat-resistant ceramic. In addition, in the pebble bed type high temperature gas-cooled reactor, the fuel ball with a high density moves while rolling on the surface of the graphite block, and therefore, high strength is required.

In view of the foregoing problems, an object of the present invention is to provide a production method of a nuclear reactor structure having high durability.

### Solution to Problem

In order to solve, the above-described problem, a production method of a nuclear reactor structure of the present invention includes,

(1) a core material processing step of processing a core material including graphite into a quadrangular prism, a bottom surface of which is an approximately isosceles trapezoid, a step of obtaining a base material by covering the core material with an aggregate including a ceramic fiber, and a CVD step of putting the base material into a CVD reactor and forming a SiC matrix in gaps of the aggregate, thereby forming a ceramic/ceramic composite material on a surface of the core material.

(2) The step of obtaining the base material includes a step of impregnating a resin after covering the core material with the aggregate.

(3) The step of obtaining the base material includes a step of heating after the step of impregnating the resin.

(4) The step of obtaining the base material includes a step of simultaneously covering the core material with the aggregate and a resin.

(5) The step of obtaining the base material includes a step of heating after the step of simultaneously covering the core material with the aggregate and the resin.

(6) The resin is a resin containing an organosilicon-based resin or a silicide-based ceramic particle.

(7) The aggregate is a wound body of the ceramic fiber winding the core material.

(8) The aggregate is a cloth including the ceramic fiber covering the core material.

(9) The aggregate is a woven fabric including the ceramic fiber covering the core material.

(10) The ceramic fiber is a SiC fiber.

### Advantageous Effects of Invention

According to the production method of the nuclear reactor structure of the present invention, a nuclear reactor structure capable of enhancing durability, preventing cracking, etc. from occurring, and preventing exposure of graphite as a core material from occurring can be provided. That is, since a ceramic/ceramic composite material having high durability is formed on a surface of a core material including graphite, the graphite is hardly exposed and difficultly consumed. In addition, according to the production method of a nuclear reactor structure of the present invention, since the core material occupying the majority is graphite, and the ceramic/ceramic composite material covers the surface of the core material, a production method of a nuclear reactor structure that scarcely affects the capability for neutron moderation of the graphite and has excellent durability can be provided.

### BRIEF DESCRIPTION OF DRAWINGS

FIG. 1 is a schematic view showing an example of a pebble bed type nuclear reactor using a nuclear reactor structure according to the present invention.

FIG. 2 is a schematic view showing an example of a pebble accommodating space constituted of a nuclear reactor structure according to the present invention, in which (a) is a longitudinal cross section, and (b) is a lateral cross section.

FIG. 3 is a block diagram showing an example of a production process of a nuclear reactor structure according to the present invention, in which (A) is a core processing step; (B) is a step of obtaining a base material; (C) is a CVD step; and (B1) to (B5) are five step patterns of the step (B) of obtaining a base material.

FIG. 4 shows the steps (A) to (C) of FIG. 3, in which (a1) to (a3) are each a conceptual perspective view; (b1) to (b3) are each a conceptual cross-sectional view; (a1) and (b1) are each concerned with the core process step (A); (a2) and (b2) are each concerned with the step (B) of obtaining a base material; and (a3) and (b3) are each concerned with the CVD step (C).

FIG. 5 is a conceptual view showing a specific example of the step (B) of FIG. 3, in which (a) is concerned with spray coating; (b) is concerned with sheet sticking; (c) is concerned with a nuclear reactor structure by (a) and (b); (d) is concerned with winding; and (e) is concerned with a nuclear reactor structure by (d).

### DESCRIPTION OF EMBODIMENTS

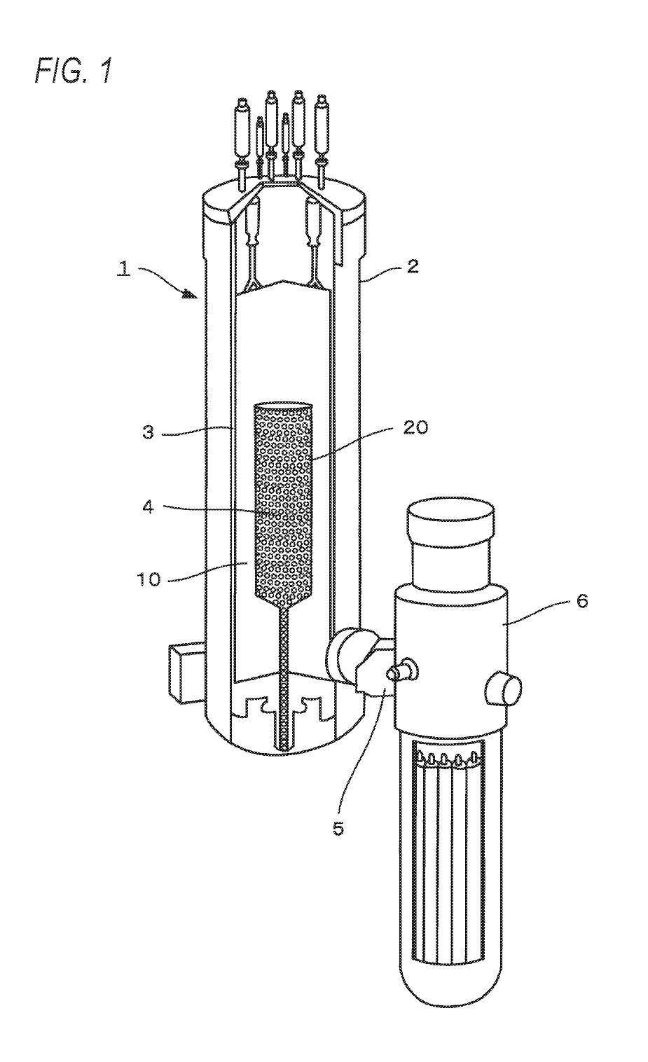

Preferred embodiments of the production method of a nuclear reactor structure according to the present invention are described in detail on the basis of FIGS. 1 to 5.

FIG. 1 is a schematic view showing an example of a pebble bed type nuclear reactor (high temperature gas-cooled reactor). In a pebble bed type nuclear reactor 1, a reactor core 3 is accommodated within a nuclear reactor vessel 2, and a plurality of pebbles 4 that are a fuel ball are loaded within the reactor core 3. In the reactor core 3, a pebble accommodating space 20 configured by, for example, graphite blocks that are a plurality of nuclear reactor structures 10 in the upper part, the lower part, and the surrounding is formed. In addition, the reactor core 3 is configured by piling up the plurality of nuclear reactor structures 10, thereby minimizing the leakage amount of neutrons to the outsides as far as possible. In addition, the lower part of the nuclear reactor vessel 2 is connected to a piping 5 for coolant, and the upper part thereof is coupled with a power conversion apparatus 6 having a power generator in the upper part, a gas turbine or a compressor in the middle, and a cooler in the lower part, respectively.

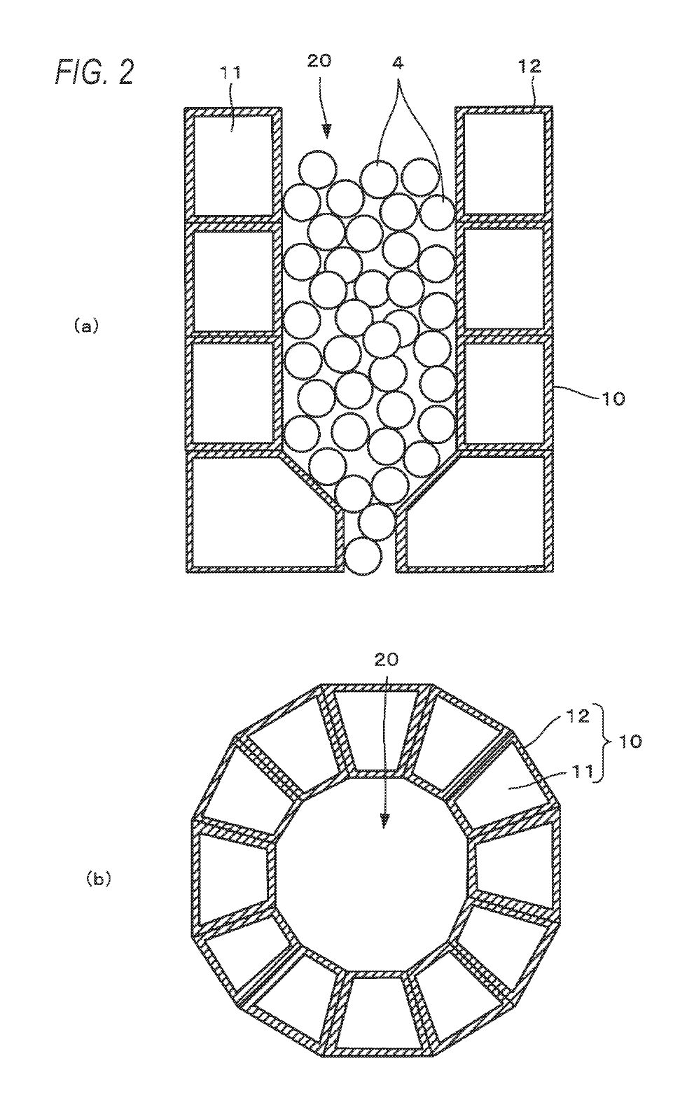

FIG. 2 is a schematic view showing an example of the pebble accommodating space 20 constituted of the nuclear reactor structures 10 of the present embodiment, in which (a) is a longitudinal cross section, and (b) is a lateral cross section.

The pebbles 4 to be loaded within the pebble accommodating space 20 have a spherical shape having a diameter of about 6 cm and for example, have a structure in which a fuel region configured by a large number of covered fuel particles containing uranium oxide as a nuclear fuel substance and a graphite matrix involving the covered fuel particles is surrounded by a graphite shell. Then, the pebble 4 is completed in such a manner that in order to contain this covered fuel particle in a graphite material working as a neutron moderator, the covered fuel particle is mixed with a graphite powder, filled within a spherical molding die, and then subjected to primary pressing to produce a primary ball (core); this primary ball is subjected to secondary pressing together with a graphite powder to form a spherical particle with shell; and in order to process this into a true spherical shape, the resulting spherical particle is subjected to surface grinding, followed by pre-calcination and calcination.

The nuclear reactor structure 10 configuring the pebble accommodating space 20 includes a core material 11 including graphite and a ceramic/ceramic composite material 12 covering the surface of the core material 11. In detail, the core material 11 is covered by an aggregate 13 including a ceramic fiber as described later to form a base material; the base material is put into a CVD furnace; and a SiC matrix is formed in gaps of the aggregate 13, thereby forming the ceramic/ceramic composite material 12 on the surface of the core material 11. In addition, in the present embodiment, the nuclear reactor structure 10 is formed in a quadrangular prism, a bottom surface of which is an approximately isosceles trapezoid, thereby forming the pebble accommodating space 20 in a columnar shape. According to this structure, the graphite is able to efficiently moderate the neutrons generated from the nuclear fuel substance to convert into heat energy.

The pebble 4 is formed by solidifying particles prepared by covering the nuclear fuel with pyrolytic carbon, SiC, or the like, and therefore, the pebble 4 is hard and has high ability of wearing the nuclear reactor structure 10. In consequence, by covering the nuclear reactor structure 10 with a substance having the same material quality as SiC that is the hardest among those contained in the pebble 4, even when a pressure is applied from the pebble 4, it becomes possible to render the nuclear reactor structure 10 to be hardly broken. In addition, the ceramic/ceramic composite material 12 including SiC is less in neutron absorption, and therefore, it scarcely affects a chain reaction of nuclear fission.

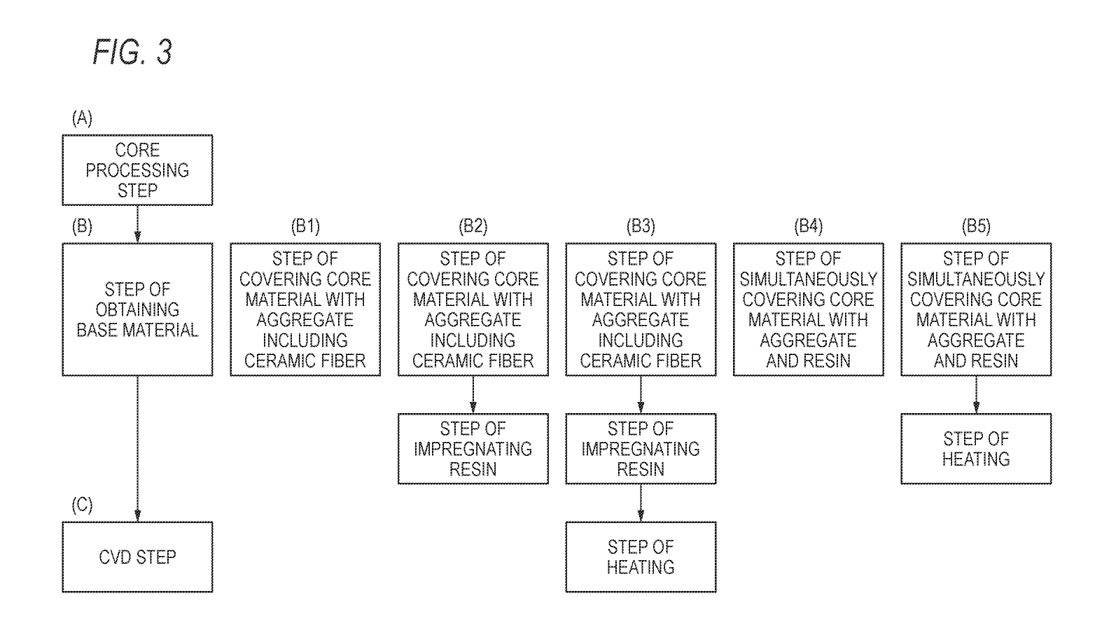

A production process of the nuclear reactor structure 10 is explained by reference to FIGS. 3 to 5.

A basic production process includes three steps of (A) a core material processing step, (B) a step of obtaining a base material, and (C) a CVD step.

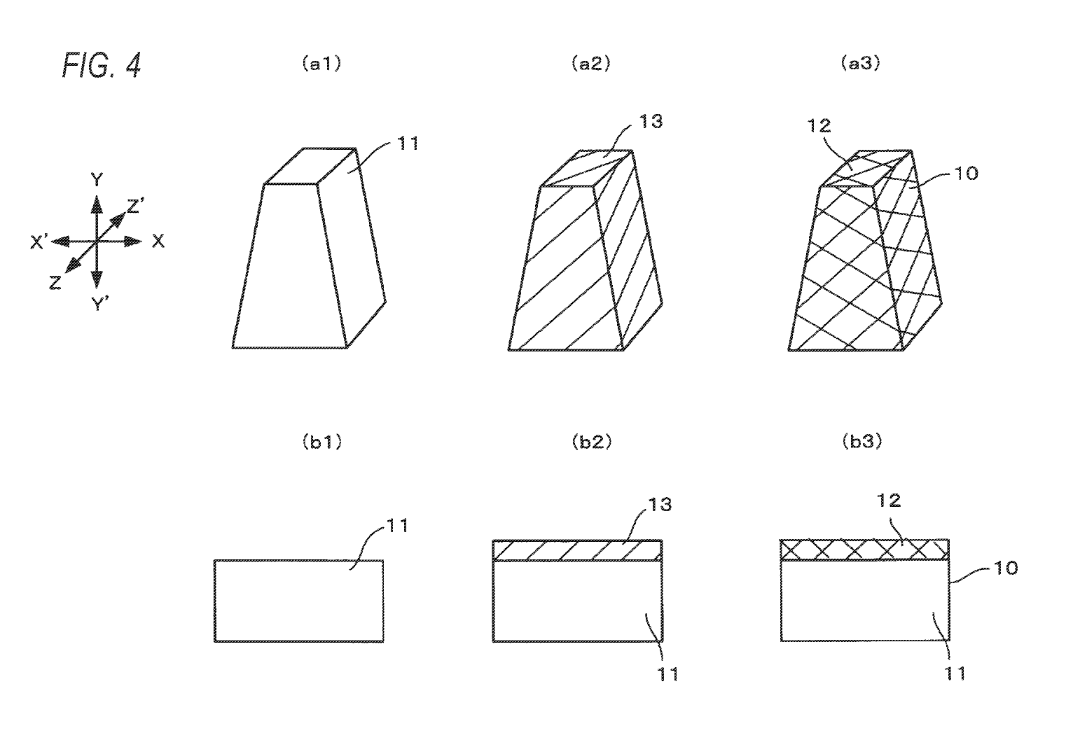

In the core material processing step (A), the core material 11 including graphite is processed into a quadrangular prism, a bottom surface of which is an approximately isosceles trapezoid (see FIG. 3 and FIGS. 4(a1) and 4(b1)). In FIGS. 4(a1) to 4(a3), the nuclear reactor structure is described sideways, and actually, it is used in such a manner that the Z-Z′ direction is a vertical direction. For this reason, the core material 11 is formed in a shape of quadrangular prism, whose cross section in the X-Y plane is formed in an approximately isosceles trapezoid and whose bottom surface is also formed in an approximately isosceles trapezoid.

In the step (B) of obtaining a base material, the core material 11 is covered with an aggregate 13 including a ceramic fiber to obtain the base material (see FIG. 3 and FIGS. 4(a2) and 4(b2)).

In the CVD step (C), the base material is put into a CVD furnace, and a SiC matrix is formed in gaps of the aggregate 13, thereby forming the ceramic/ceramic composite material 12 on the surface of the core material 11 (see FIG. 3 and FIGS. 4(a3) and 4(b3)).

The gaps of the aggregate 13 are gaps formed among the ceramic fibers configuring the aggregate 13. In general, as for a fibrous substance, the space can be completely filled with a fibrous substance under an extremely restricted condition. The restricted condition is, for example, a condition under which the following state is formed.
In a cross section orthogonal to the fibrous substance, no gap exists, and the fibrous substance is arranged linearly and in the same direction. For example, a fibrous substance of triangular, quadrangular, or pentagonal prism is disposed.
A tabular substance is laminated, and a fibrous substance is filled in the tabular substance without gaps. The term “tabular” means, for example, a state where a fibrous substance of quadrangular prism is arranged laterally to constitute a tabular substance, or a state where a fibrous substance of quadrangular prism is wound up in a plane.

For this reason, in the case where the ceramic fiber is a woven fabric, a nonwoven fabric, or a papermaking sheet-like body, or in the case where the cross section of the ceramic fiber is circular, gaps are inevitably formed. The gap includes, in the addition to the case where the ceramic fibers are far from each other, a cavity of the surface formed by the adjacent ceramic fibers to each other.

In the present embodiment, the core material 11 is covered with the ceramic fiber-containing aggregate 13, and also a CVD step of forming the SiC matrix is included. Accordingly, the nuclear reactor structure 10 capable of more enhancing the durability, preventing cracking, etc. from occurring, and preventing exposure of graphite of the core material 11 from occurring is provided. For this reason, since in the nuclear reaction structure, the core material occupying the majority is graphite, and the ceramic/ceramic composite material covers the surface of the core material, a production method of a nuclear reactor structure that scarcely affects the capability for neutron moderation of the graphite and has excellent durability can be provided.

In the above-described matrix formation, the ceramic matrix is filled in the surrounding of the ceramic fiber that is the aggregate 13. In the CVD process, the core material 11 is put into the CVD furnace, and a raw material gas is introduced in a heated state thereinto. When the raw material gas is diffused within the CVD furnace and brought into contact with the heated aggregate 13, pyrolysis occurs, whereby the ceramic matrix corresponding to the raw material gas is formed on the surface of the ceramic fiber constituting the aggregate 13.

In the case wherein the objective ceramic matrix is SiC, a mixed gas of a hydrocarbon gas and a silane-based gas, an organosilane-based gas including carbon and silicon, and the like can be utilized. As such a raw material gas, a gas in which hydrogen is substituted with a halogen can also be utilized. As the silane-based gas, chlorosilane, dichlorosilane, trichlorosilane, and tetrachlorosilane can be utilized; and in the case of the organosilane-based gas, methyltrichlorosilane, methyldichlorosilane, methylchlorosilane, dimethyldichlorosilane, trimethyldichlorosilane, and the like can be utilized. In addition, these raw material gases may be properly mixed and used, and furthermore, hydrogen, argon, or the like can also be used as a carrier gas. Hydrogen which is used as the carrier gas is able to participate in adjustment of the equilibrium.

Next, the process of obtaining the base material is described in detail by reference to FIG. 3. In the present embodiment, in the step (B) of obtaining the base material, five step patterns are existent. In FIG. 3, the five step patterns are expressed by from (B1) to (B5). (B1) is a step of covering the core material 11 with the aggregate 13 including a ceramic fiber. In (B2), a step of impregnating a resin is added after the above-described step (B1). In (B3), a step of further heating is added after the above-described step (B2). (B4) is a step of simultaneously covering the core material 11 with the aggregate 13 and the resin. In (B5), a step of heating is added after the above-described step (B4).

In the step (B1) of covering the core material 11 with the aggregate 13 including a ceramic fiber, aggregates including ceramic fibers in various forms can be utilized. Examples thereof include a sheet-like fiber, a single fiber, a strand resulting from bundling single fibers, a chopped fiber resulting from cutting a ceramic fiber, a milled fiber resulting from milling a ceramic fiber, and the like. Examples of the sheet-like fiber include a woven fabric and a nonwoven fabric. Furthermore, examples of the nonwoven fabric include a papermaking sheet resulting from papermaking a chopped fiber or milled fiber, a felt sheet resulting from laminating a chopped fiber or milled fiber, and the like. As for the aggregate covering the core material, though such materials may be used alone, they can also be used in combination. For example, a strand-like ceramic fiber may be provided outside the sheet-like ceramic fiber. The strand-like ceramic fiber tightens the sheet-like ceramic fiber, whereby the base material and the aggregates can be brought into intimate contact with each other. Furthermore, the base material and the ceramic/ceramic composite material obtained therefrom can be brought into intimate contact with each other.

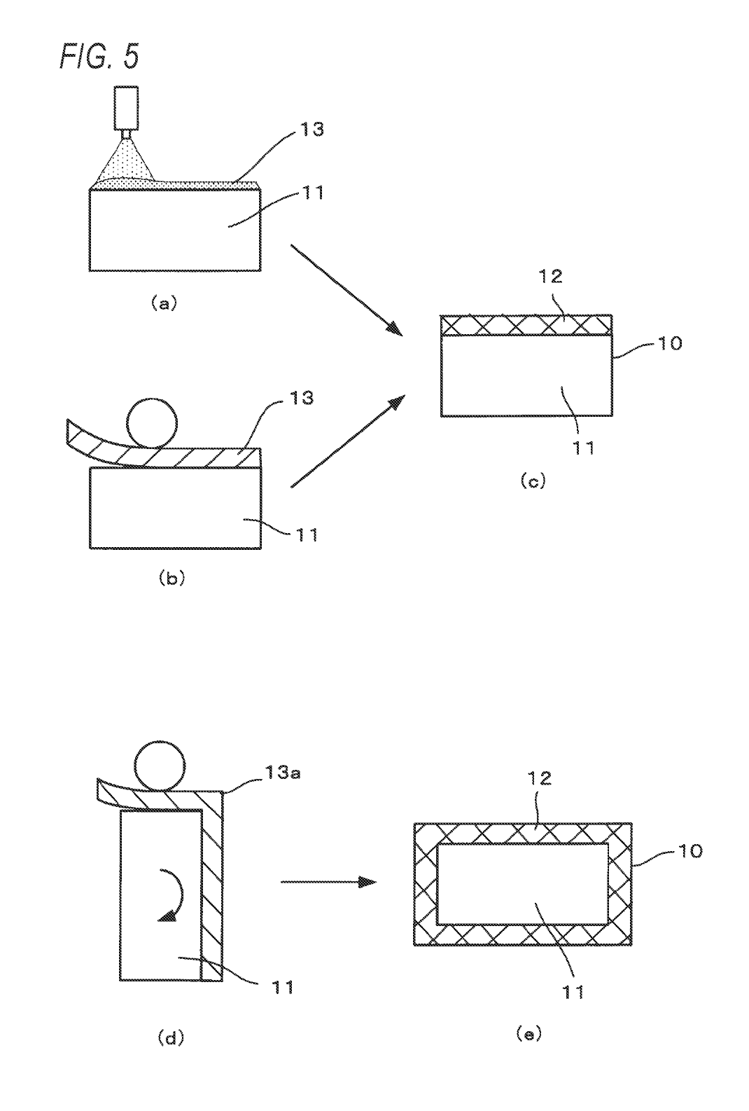

Next, the step (B1) of covering the core material 11 with the aggregate 13 including a ceramic fiber is specifically explained. For example, the ceramic fiber is applied onto the surface of the core material 11 utilizing method of blowing the ceramic fiber, such as a milled fiber, etc., together with a solvent onto the surface of the core material 11 by means of spraying or the like (see FIG. 5(a)), or coating it together with a solvent using a coater or the like; a method of sticking a sheet-like ceramic fiber onto the surface of the ceramic fiber 11 (see FIG. 5(b)); or the like. Then, the ceramic/ceramic composite material 12 can be formed on the surface of the core material 11 by the CVD step (C) (see FIG. 5(c)).

In addition, it is also possible to wind a ceramic fiber in a single fiber or strand-like state, etc. around the entire surface of the core material 11, thereby forming the aggregate 13 in a wound body 13a (see FIG. 5(d)), and the ceramic/ceramic composite material 12 can be formed on the surface of the core material 11 by the CVD step (C) (see FIG. 5(e)).

The winding method is not particularly limited. For example, hoop winding of winding the ceramic fiber in a ring while rotating the core material 11; helical winding of helically winding the ceramic fiber while keeping gaps between the ceramic fibers; and the like can be utilized, and a combination thereof can also be used. In addition, in the case where the ceramic fiber is made of a combination of hoop winding and helical winding, a ceramic fiber-reinforced ceramic composite material with high strength, in which a large number of points of contact of the ceramic fibers crossing each other are present at an interface thereof, can be obtained.

In the embodiment of FIG. 2, an example in which the entire surface of the core material 11 is covered with the aggregate 13 to form the ceramic/ceramic composite material 12 by the CVD method is shown. The ceramic/ceramic composite material 12 may be formed on only an inner wall facing the pebble accommodating space 20. It is possible to properly select the forming surface of the ceramic/ceramic composite material 12 in conformity with the use condition.

In (B2), a step of impregnating a resin is added after the above-described step (B1). In order to increase the adhesion of the ceramic fiber to the core material 11 to obtain the aggregate 13 with higher strength, the resin to be impregnated contains, for example, an organosilicon-based resin or a silicide-based ceramic particle. In the case of using an organosilicon-based resin, the resin per se is converted into a ceramic under heating. Examples of the organosilicon-based resin include a polycarbosilane and the like. The polycarbosilane is converted into SiC under heating.

In the case of using a silicide-based ceramic particle, the ceramic particle is able to form the SiC matrix in the gaps of the aggregate. The silicide-based ceramic particle is not particularly limited, and examples thereof include SiC, SiO₂, and the like. A resin which is used together with the silicide-based ceramic resin is not particularly limited, and for example, a phenol resin, polyvinyl alcohol, polyethylene glycol, and the like can be utilized. Such a resin functions as a binder. In addition, in the case of SiO₂ as the silicide-based ceramic particle, SiO₂ can be bonded to Si to become a raw material of the SiC matrix.

The method of heating the resin is not particularly limited, on the occasion of undergoing the CVD step of (C), the resin can be treated at the same time of heating before introducing the raw material gas; but, a heating step may also be separately added (see FIG. 3(B3)).

In the step of impregnating a resin, which is adopted in the production method of FIG. 3(B2) or 3(B3), a solution containing the resin or the molten resin may be blown by means of spraying or the like, dipping, painting with a brush, or the like. In addition, it is possible to melt a powder or film-like solid resin, thereby impregnating the molten resin.

In (B3), a step of heating is added after the above-described step (B2). In this step of obtaining a base material, by adding the step of heating, before the CVD step, the ceramic fiber and the impregnated resin can be firmly bonded to each other, the aggregate does not rise in the CVD step, and the base material and the ceramic/ceramic composite material can be brought into intimate contact with each other. In addition, a decomposed gas is scarcely generated in the inside of the CVD furnace, and the inside of the CVD furnace can be made to be hardly contaminated. Thus, the purity of the SiC matrix to be formed within the CVD furnace can be increased, and the performance as a nuclear reactor structure, such as capability for neutron moderation, etc., can be increased.

In addition, in the step (B) of obtaining a base material, after the step of (B4) of simultaneously covering the core material 11 with the aggregate 13 and the resin, the ceramic/ceramic composite material 12 can also be formed by the CVD step (C). The simultaneous covering with the aggregate 13 and the resin can be realized by containing the resin in the aggregate 13 from the beginning. Though a method of containing the resin in the aggregate 13 is not particularly limited, for example, a method of dipping the aggregate in the resin or a resin solution, a method of dispersing a powdered or fibrous resin in the aggregate, and the like can be applied. In order to increase the adhesion of the ceramic fiber to the core material 11 to obtain the aggregate 13 with higher strength, for example, the resin can contain an organosilicon-based resin or a silicide-based ceramic particle. In addition, a step of heating can be added after the step of (B4) as in the step of (B5).

Then, the aggregate 13 including a ceramic fiber, which covers the core material 11, may be a cloth or a woven fabric including a ceramic fiber.

Though the ceramic fiber is not particularly limited so long as it has heat resistance and strength and has a low neutron absorption cross section, for example, ZrC, SiC, or a carbon fiber can be utilized. In particular, the ceramic fiber is desirably a SiC fiber. Since the SiC fiber is excellent in corrosion resistance and oxidation resistance and has high strength, by using SiC, even in the case where the ceramic matrix is damaged in a high-temperature corrosive atmosphere, the ceramic fiber stops development of cracking, whereby it can be safely used. In addition, since the SiC fiber is less in neutron absorption, it scarcely affects a chain reaction of nuclear fission.

The invention is not restricted to the above-described embodiment, and suitable modifications, improvements, and the like can be made. Moreover, the materials, shapes, dimensions, numerical values, forms, numbers, installation places, and the like of the components are arbitrarily set as far as the invention can be attained, and not particularly restricted.

It is to be noted that the present application is based on a Japanese patent application filed on Dec. 22, 2014 (Japanese Patent Application No. 2014-258777), the entireties of which are incorporated by reference.

### INDUSTRIAL APPLICABILITY

The production method of a nuclear reactor structure according to the present invention is applicable to an application of a nuclear reactor utilizing a pebble.

### REFERENCE SIGNS LIST

1: Pebble bed type nuclear reactor
2: Nuclear reactor vessel
3: Reactor core
4: Pebble
10: Nuclear reactor structure
11: Core material
12: Ceramic/ceramic composite material
13: Aggregate
20: Pebble accommodating space

1. A production method of a nuclear reactor structure, comprising:
a core material processing step of processing a core material including graphite into a quadrangular prism, a bottom surface of which is an approximately isosceles trapezoid,
a step of obtaining a base material by covering the core material with an aggregate including a ceramic fiber, and
a CVD step of putting the base material into a CVD reactor and forming a SiC matrix in gaps of the aggregate, thereby forming a ceramic/ceramic composite material on a surface of the core material.

2. The production method of the nuclear reactor structure according to claim 1,
wherein the step of obtaining the base material includes a step of impregnating a resin after covering the core material with the aggregate.

3. The production method of the nuclear reactor structure according to claim 2,
wherein the step of obtaining the base material includes a step of heating after the step of impregnating the resin.

5. The production method of the nuclear reactor structure according to claim 1,
wherein the step of obtaining the base material includes a step of simultaneously covering the core material with the aggregate and a resin.

5. The production method of the nuclear reactor structure according to claim 4,
wherein the step of obtaining the base material includes a step of heating after the step of simultaneously covering the core material with the aggregate and the resin.

6. The production method of the nuclear reactor structure according to claim 2,
wherein the resin is a resin containing an organosilicon-based resin or a silicide-based ceramic particle.

7. The production method of the nuclear reactor structure according to claim 1,
wherein the aggregate is a wound body of the ceramic fiber winding the core material.

8. The production method of the nuclear reactor structure according to claim 1,
wherein the aggregate is a cloth including the ceramic fiber covering the core material.

9. The production method of the nuclear reactor structure according to claim 8,
wherein the aggregate is a woven fabric including the ceramic fiber covering the core material.

10. The production method of the nuclear reactor structure according to claim 1,
wherein the ceramic fiber is a SiC fiber.
